(19) United States
(12) Patent Application Publication
(10) Pub. No.: US 2013/0146133 A1
(43) Pub. Date: Jun. 13, 2013

(54) THIN FILM PHOTOVOLTAIC SOLAR CELL DEVICE

(71) Applicants: John P. Lemmon, Kennewick, WA (US); Evgueni Polikarpov, Richland, WA (US); Wendy D. Bennett, Kennewick, WA (US)

(72) Inventors: John P. Lemmon, Kennewick, WA (US); Evgueni Polikarpov, Richland, WA (US); Wendy D. Bennett, Kennewick, WA (US)

(73) Assignee: BATTELLE MEMORIAL INSTITUTE, Richland, WA (US)

(21) Appl. No.: 13/324,710

(22) Filed: Dec. 13, 2011

(51) Int. Cl. H01L 31/0336; H01L 31/18

(52) U.S. Cl. 136/256; 438/94; 257/E31.015; 257/E31.005

(57) ABSTRACT

A thin-film photovoltaic solar cell device is disclosed. A transparent conductive oxide (TCO) layer is disposed on a substrate as a front contact. A window layer is disposed on the TCO layer. A metal oxide layer is disposed on the window layer. An absorber layer is disposed on the metal oxide layer. A back contact layer is disposed on the absorber layer. In one embodiment, the device includes a high resistance barrier (HRT) layer interposed between the window layer and the TCO layer.

### STATEMENT REGARDING FEDERALLY SPONSORED RESEARCH OR DEVELOPMENT

The invention was made with Government support under Contract DE-AC-05-RL01830, awarded by the U.S. Department of Energy. The Government has certain rights in the invention.

### TECHNICAL FIELD

This invention relates to solar cell devices. More specifically, this invention relates to a thin-film photovoltaic solar cell device that includes a metal oxide layer disposed on a window layer to improve overall efficiency increase in solar cells.

### BACKGROUND OF THE INVENTION

Early studies on CdTe solar cells were based on both substrate and superstrate structures. Furthermore, cells were fabricated with single crystals of CdTe and also polycrystalline films of CdTe. Eventually, efforts primarily focused on cells based on polycrystalline CdTe films in a superstrate structure. Since 1993, three groups have fabricated laboratory cells with an efficiency of approximately 16%. (See Wu, X., Solar Energy 2004, 77, 803-814; Ohyama, H. In 16.0% Efficient Thin-Film CdS/CdTe Solar Cells, 26th IEEE Photovoltaic Specialist Conference, Sep. 30, 1997; IEEE: 1997; pp 343-346; and Britt, J.; Ferekides, C., Applied Physics Letters 1993, 62, 28-51-2852.) Detailed cell properties are given in Table 1. Besides having similar values for V_{oc}, J_{sc} and FF, these cells have similar structures. Referring to FIG. 1, all cells were based on a CdS/CdTe heterojunction, a superstrate structure on a SnO₂ coated borosilicate glass with an AR coating of MgF₂. All cells utilized CSS growth of CdTe at fairly high temperatures so that all devices probably had an interdiffused region of CdSₓCdTe₁₋ₓ. The Britt and Wu cells had CdS grown by CBD, whereas the Ohyama device incorporated CdS grown by MOCVD. Finally, the Wu cell had a HRT (high resistance TCO) layer whereas the other cells did not utilize a HRT film.

Also shown in Table 1 are values of CdTe cell J-V properties that were identified by McCandless and Sites as reasonable expectations.¹⁰ The three champion cells all had values of J_{sc} either equal or close to the value of 26 mA/cm². Their values of V_{oc} and FF were less than values required in order for the efficiency to approach 19%. Increases in V_{oc} and FF in future CdTe cells will require reductions in current losses due to Shockley-Reed-Hall (SRH) recombination. These losses occur in the interface region of the heterojunction and extend through the depletion region and region of high optical generation.

The J-V characteristics of the most efficient CdTe cells can be represented by the simple single diode model using the diode equation.¹³ In particular, the forward current characteristics can be explained by the following equation (using the notation of Reference 13):

J=Jₒexp[(V−JR)/AkT]−J_{sc}+V/r

For the Wu Cell:
Jo=1×10-9 A/cm2
A=1.9
R=Series Resistance=1.8 ohm-cm2
r=Shunt Resistance=2500 ohm-cm2

Similar values of J-V parameters were reported for the Britt cell. The diode quality factor, A, is on the order of 2 for these champion cells which indicates that the power losses in the CdTe thin film cell are dominated by SRH recombination. These losses are apparently a result of electron-hole recombination via interband states in the CdS—CdTe interface and depletion regions.

High efficiency CdTe cells fabricated by CSS are optimized by use of post-deposition CdCl₂ treatment step, use of high quality TCO materials, and reduced CdS thickness in conjunction with a HRT layers. The themochemistry and diffusion reaction kinetics of the thin film CdS—CdTe couple under high temperature film growth and during post-deposition processing promote formation of a diffusion layer at the CdS—CdTe interface, which results in CdS consumption and lowered CdTe band gap.¹⁴ The HRT layer can also react with CdS and is thought to add to further consumption and morphological changes of CdS.^{15,16} Both effects have a direct impact on Voc: reduced CdS thickness increases difficulty in controlling junction uniformity, and reduced CdTe band gap lowers the built in potential interdiffusion is enhanced during CdCl₂ treatment by elevated grain boundary diffusivity in the presence of CdCl₂ and O₂, allowing for CdCl₂ and O₂ to penetrate the film and reach the CdS—CdTe interface. The enhanced diffusion arises from formation of cadmium vacancies (V_{cd}) at the grain surfaces, resulting in elevated p-type conduction that serves to confine minority carriers (electrons), and improving collection.¹⁷⁻¹⁹ (High Voc can be obtained without CdCl₂ treatment, however good collection requires the treatment.) The interdiffusion layer has been considered helpful in reducing interface states by reducing lattice mismatch, although the phase system has a miscibility gap and does not have continuous composition.²⁰ More importantly, interdiffusion is an indicator that CdCl₂ and O₂ have penetrated the entire CdTe film, and optimal post-deposition CdCl₂ treatment depends on CdTe thickness and grain size distribution.²¹ As mentioned above, alloy formation in the interdiffused region lowers the band gap in both CdS and CdTe, which is undesirable.^{22, 23} Recently it has been speculated that the p-n junction may exist between the Te-rich CdTe₁₋ₓSₓ layer and the CdTe layer in cells with high Voc and can be considered a quasi-homo-junction.²⁴ This mechanism is partially supported by the highest reported Voc of 890 mV is predicted to be a buried homojunction.

### SUMMARY OF THE INVENTION

The present invention is directed to a thin-film photovoltaic solar cell device. In one embodiment, the solar cell device comprises a substrate and a transparent conductive oxide (TCO) layer on the substrate as a front contact. The device also includes a window layer disposed on the TCO layer and a metal oxide layer disposed on the window layer. The device further includes an absorber layer disposed on the metal oxide layer and a back contact layer disposed on the absorber layer.

In one embodiment, the substrate comprises glass. The glass may be borosilicate glass.

In one embodiment, the TCO comprises SnO₂, the window layer comprises cadmium sulfide, and the absorber layer comprises cadmium telluride. The window layer may have a thickness of about 100 nm or less.

In one embodiment, the metal oxide layer consists of at least one of the following: SnO₂, In₂O₃, TiO₂, Ta₂O₅, CuAlO₂, MoO₃, WO₃, TaOₓN_{y}, MWₓO_{y}, MMoₓO_{y}, MTaₓO_{y}, MTiₓO_{y}, MNbₓO_{y}, MSnO₄. The metal oxide layer may have a thickness of about 5 nm or less.

In some embodiments, the solar cell device further comprises a high resistance barrier (HRT) layer interposed between the window layer and the TCO layer.

In another embodiment of the present invention, a method of fabricating a thin-film photovoltaic solar cell device is disclosed. The method comprises depositing a transparent conductive oxide (TCO) layer on a substrate as a front contact. The method also comprises depositing a window layer on the TCO layer and depositing a metal oxide layer on the window layer. The method also comprises depositing an absorber layer on the metal oxide layer. The method further comprises depositing a back contact layer on the absorber layer. In one embodiment, the method also comprises interposing a high resistance barrier (HRT) layer between the window layer and the TCO layer.

In another embodiment of the present invention, a thin-film photovoltaic solar cell device that has a transparent conductive oxide (TCO) front contact layer and a back contact layer is disclosed. The solar cell device includes a metal oxide layer interposed between a window layer and an absorber layer.

In another embodiment of the present invention, a method of preventing interdiffusion between a window layer and an absorber layer in a thin-film photovoltaic solar cell device that has a transparent conductive oxide (TCO) front contact layer and a back contact layer is disclosed. The method comprises interposing a metal oxide layer between the window layer and the absorber layer.

### BRIEF DESCRIPTION OF THE DRAWINGS

FIG. 1 shows results of three prior laboratory CdTe solar cell efficiency studies by Wu et al., Ohyama et al, and Britt et al., which includes values for V_{oc}, J_{sc} and FF. The values identified by McCandless & Sites are based on reasonable expectations.

FIG. 2 is an illustration of a thin-film photovoltaic solar cell device, in accordance with one embodiment of the present invention.

FIG. 3 shows a listing of suggested materials and their desired properties for the metal oxide layer and the high resistance barrier (HRT) layer of a thin-film photovoltaic solar cell device, in accordance with one embodiment of the present invention.

FIG. 4A shows J-V characteristics of the thin-film photovoltaic solar cell device as a function of ILM (window) layer thickness, in accordance with one embodiment of the present invention. Each curve corresponds to different thicknesses of the ILM layer.

FIG. 4B shows test results of the thin-film photovoltaic solar cell device using different thicknesses for the ILM (window) layer, including a control run without the ILM layer, in accordance with one embodiment of the present invention. The test results include values for voltage (V_{oc}) in millivolts, current density (J_{sc}) in mA/Cm², fill factor (FF), and efficiency (Eff).

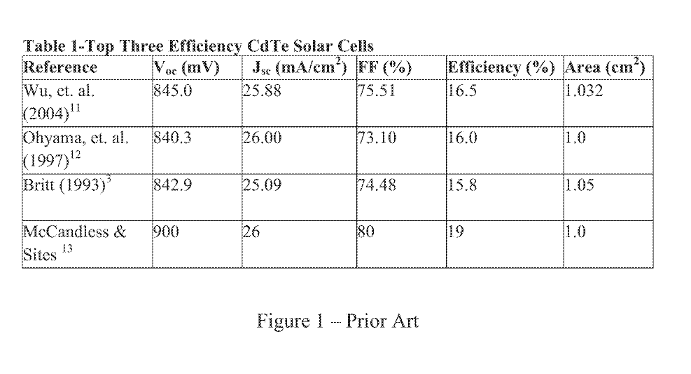

### DETAILED DESCRIPTION OF THE PREFERRED EMBODIMENTS

The present invention provides, in certain embodiments, a refined window layer and corresponding interfaces in thin-film solar cell technology which leads to increased performance and durability. The present invention, in one embodiment, combines an optional high resistance barrier (HRT) layer on a transparent conductive oxide (TCO) side of a window layer, and a thin interlayer material (ILM) between the window layer and an absorber layer. By optimizing physical (crystal lattice matching), chemical (phase formation, diffusion control) and electronic properties of the solar cell, significant flexibility in cell chemistry and processing parameters can be employed to improve junction properties and maximize optical throughput, leading to an overall efficiency increase in thin film photovoltaic solar cells.

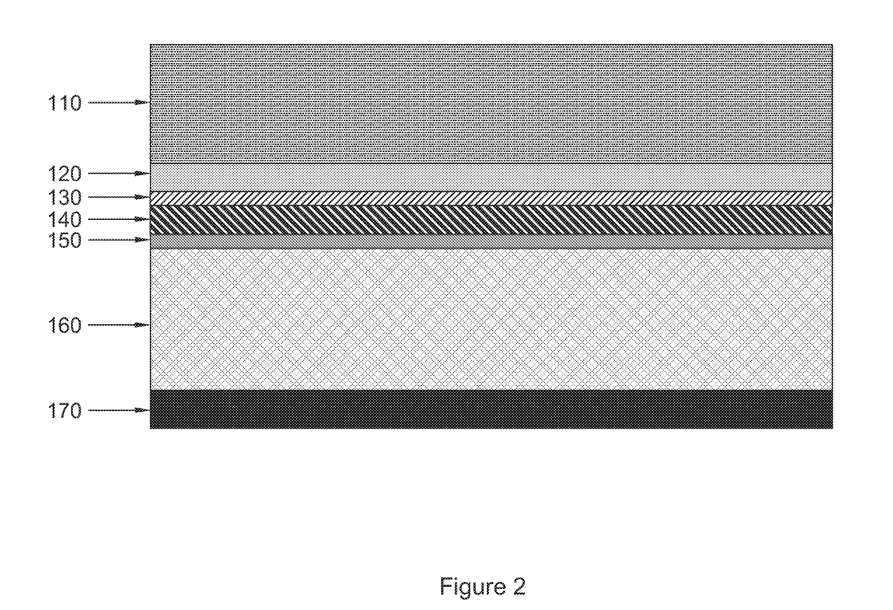

FIG. 2 is an illustration of a thin-film photovoltaic solar cell device 100, in accordance with one embodiment of the present invention. The device 100 comprises a substrate 110 and a transparent conductive oxide (TCO) layer 120 on the substrate 110 as a front contact. The device 100 also includes a window layer 140 disposed on the TCO layer 120 and a metal oxide layer (i.e., ILM) 150 disposed on the window layer 140. The device 100 further includes an absorber layer 160 disposed on the metal oxide layer 150 and a back contact layer 170 disposed on the absorber layer 160. In one embodiment, the device 100 further includes an optional high resistance barrier (HRT) layer 130 interposed between the window layer 140 and the TCO layer 120. In another embodiment, the substrate 110 is coated with indium tin oxide (ITO).

In one embodiment, the substrate 110 comprises glass such as borosilicate glass. In certain embodiments, a zinc stannate is deposited on the glass substrate 110, and the substrate 110 is coated with indium tin oxide (ITO).

In some embodiments, the TCO layer 120 comprises SnO₂, the window layer 140 comprises cadmium sulfide and the absorber layer 160 comprises cadmium telluride.

In some embodiments, the window layer 140 has a thickness of about 100 nm or less and the metal oxide layer 150 has a thickness of about 5 nm or less. The metal oxide layer may be at least one of the following: SnO₂, In₂O₃, TiO₂, Ta₂O₅, MoO₃, WO₃, CuAlO₂, TaOₓN_{y}, MWₓO_{y}, MMoₓO_{y}, MTaₓO_{y}, MTiₓO_{y}, MNbₓO_{y}, MSnO₄.

In one embodiment, the metal oxide layer 150 is deposited onto the window layer 140 prior to deposition of the absorber layer 160. Many improvements are realized by depositing the metal oxide layer 150 onto the window layer 140. These include, but are not limited to, the following:
Allow refinement of lattice matching between CdS and CdTe
Inhibit diffusion of impurities from the back contact into CdS
Provide a good electron affinity adjustment between CdTe and CdS
Reduce recombination at the CdTe interface
Reduce interdiffusion of CdS and CdTe
Provide improved surface on which to grow CdTe, leading to superior crystallographic and electronic quality of the CdTe and increased minority carrier lifetime

The optional HRT layer 130 provides the following improvements:
Along with the TCO, provides very high transmittance of solar photons with wavelength <850 nm
Allows use of thinner CdS layers by modifying CdS nucleation and in-plane density
Inhibiting diffusion of impurities from the borosilicate glass and TCO
Acts as a barrier to excess forward current flow through pin-holes or other defects
Acts as an etch stop during back contact processing

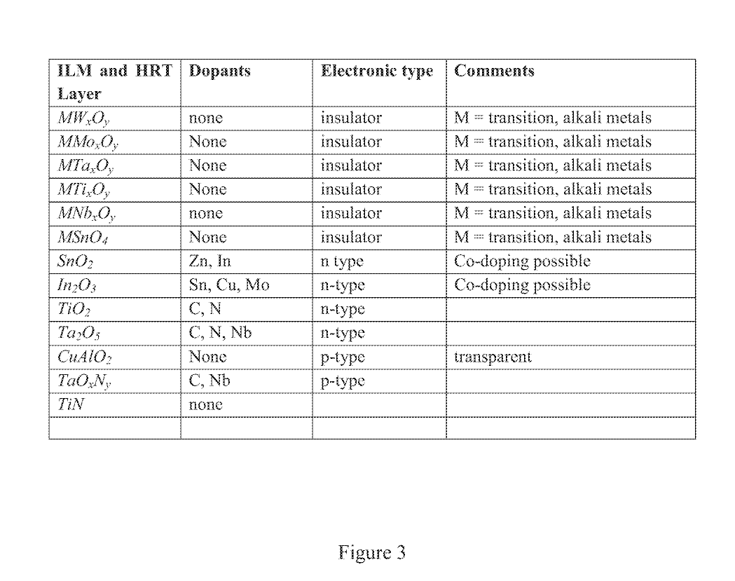

Suggested materials for the ILM and optional HRT layer, including their desired properties, are listed in FIG. 3.

This invention is further illustrated by the following examples that should not be construed as limiting.

### Experimental Section

### Materials and Set-Up

The fabrication of a thin film solar cell device, in accordance with one embodiment of the present invention, involved a multi-layer deposition approach. CdS of approximately 100 nm (+/−5 nm) was deposited onto a glass substrate having a TCO layer. A metal oxide layer (approximately 1-5 nm) was then deposited onto the CdS. CdTe was then deposited onto the substrate by close space sublimation (CSS). In the CSS step, electricity was applied to CdTe particles (approximately 4-5 micrometers thick) on a boat which caused the CdTe particles to evaporate onto the substrate and form a thin film. Following CdTe deposition, a back contact was applied. As part of the back contact formation, the post-deposition processing involved CdCl₂ treatment for surface modification and copper doping for electrical modification. The cell was then placed in a solar simulator for testing and measuring to generate V_{oc}, J_{sc}, FF and efficiency data.

### Experimental Results and Discussion

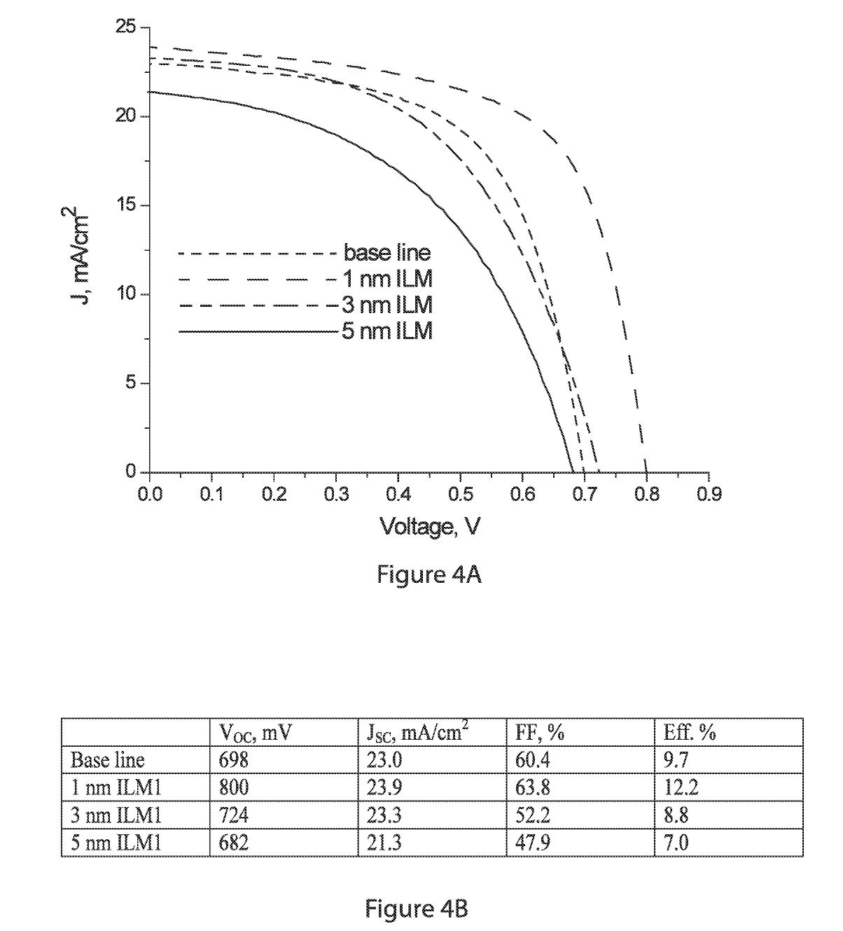

FIG. 4A shows J-V characteristics of the thin-film photovoltaic solar cell device as a function of ILM (window) layer thickness. Each curve corresponds to different thicknesses of the ILM layer.

FIG. 4B shows test results of the thin-film photovoltaic solar cell device using different thicknesses for the ILM (window) layer, including a control run without the ILM layer, in accordance with one embodiment of the present invention. The test results include values for voltage (V_{oc}) in millivolts, current density (J_{sc}) in mA/Cm², fill factor (FF), and efficiency (Eff). The device having a 1 nm thick metal oxide layer (ILM) showed an improvement in V_{oc} of approximately 100 mV over the control device (base line), which results in an increase in efficiency from 9.7% to 12.2%.

The present invention has been described in terms of specific embodiments incorporating details to facilitate the understanding of the principles of construction and operation of the invention. As such, references herein to specific embodiments and details thereof are not intended to limit the scope of the claims appended hereto. It will be apparent to those skilled in the art that modifications can be made in the embodiments chosen for illustration without departing from the spirit and scope of the invention.

We claim:

1. A thin-film photovoltaic solar cell device comprising:
a. a substrate;
b. a transparent conductive oxide (TCO) layer on the substrate as a front contact;
c. a window layer disposed on the TCO layer;
d. a metal oxide layer disposed on the window layer,
e. an absorber layer disposed on the metal oxide layer, and
f. a back contact layer disposed on the absorber layer.

2. The device of claim 1 wherein the substrate comprises glass.

3. The device of claim 2 wherein the glass comprises borosilicate glass.

4. The device of claim 1 wherein the TCO comprises SnO₂.

5. The device of claim 1 wherein the window layer comprises cadmium sulfide.

6. The device of claim 1 wherein the absorber layer comprises cadmium telluride.

7. The device of claim 1 wherein the window layer has a thickness of about 100 nm or less.

8. The device of claim 1 wherein the metal oxide layer consists of at least one of the following: SnO₂, In₂O₃, TiO₂, Ta₂O₅, MoO₃, WO₃, CuAlO₂, TaOₓN_{y}, MWₓO_{y}, MMoₓO_{y}, MTaₓO_{y}, MTiₓO_{y}, MNbₓO_{y}, MSnO₄.

9. The device of claim 8 wherein the metal oxide layer has a thickness of about 5 nm or less.

10. The device of claim 1 further comprising a high resistance barrier (HRT) layer interposed between the window layer and the TCO layer.

11. A method of fabricating a thin-film photovoltaic solar cell device comprising:
a. depositing a transparent conductive oxide (TCO) layer on a substrate as a front contact;
b. depositing a window layer on the TCO layer;
c. depositing a metal oxide layer on the window layer;
d. depositing an absorber layer on the metal oxide layer; and
e. depositing a back contact layer on the absorber layer.

12. The method of claim 11 wherein the substrate comprises glass.

13. The method of claim 12 wherein the glass comprises borosilicate glass.

14. The method of claim 11 wherein the TCO comprises SnO₂.

15. The method of claim 11 wherein the window layer comprises cadmium sulfide.

16. The method of claim 11 wherein the absorber layer comprises cadmium telluride.

17. The method of claim 11 wherein the window layer has a thickness of about 100 nm or less.

18. The method of claim 11 wherein the metal oxide layer consists of at least one of the following: SnO₂, In₂O₃, TiO₂, Ta₂O₅, MoO₃, WO₃, CuAlO₂, TaOₓN_{y}, MWₓO_{y}, MMoₓO_{y}, MTaₓO_{y}, MTiₓO_{y}, MNbₓO_{y}, MSnO₄.

19. The method of claim 18 wherein the metal oxide layer has a thickness of about 5 nm or less.

20. The method of claim 11 further comprising interposing a high resistance barrier (HRT) layer between the window layer and the TCO layer.

21. A thin-film photovoltaic solar cell device that has a transparent conductive oxide (TCO) front contact layer and a back contact layer, comprising: a metal oxide layer interposed between a window layer and an absorber layer.

22. The device of claim 21 wherein the TCO comprises SnO₂.

23. The device of claim 21 wherein the window layer comprises cadmium sulfide.

24. The device of claim 21 wherein the absorber layer comprises cadmium telluride.

25. The device of claim 21 wherein the window layer has a thickness of about 100 nm or less.

26. The device of claim 21 wherein the metal oxide layer consists of at least one of the following: SnO₂, In₂O₃, TiO₂, Ta₂O₅, MoO₃, WO₃, CuAlO₂, TaOₓN_{y}, MWₓO_{y}, MMoₓO_{y}, MTaₓO_{y}, MTiₓO_{y}, MNbₓO_{y}, MSnO₄.

27. The device of claim 26 wherein the metal oxide layer has a thickness of about 5 nm or less.

28. The device of claim 21 further comprising a high resistance barrier (HRT) layer interposed between the window layer and the TCO layer.

29. A method of preventing interdiffusion between a window layer and an absorber layer in a thin-film photovoltaic solar cell device that has a transparent conductive oxide (TCO) front contact layer and a back contact layer, wherein the method comprises: interposing a metal oxide layer between the window layer and the absorber layer.

30. The method of claim 29 wherein the TCO comprises SnO₂.

31. The method of claim 29 wherein the window layer comprises cadmium sulfide.

32. The method of claim 29 wherein the absorber layer comprise cadmium telluride.

33. The method of claim 29 wherein the window layer has a thickness of about 100 nm or less.

34. The method of claim 29 wherein the metal oxide layer consists of at least one of the following: SnO₂, In₂O₃, TiO₂, Ta₂O₅, MoO₃, WO₃, CuAlO₂, TaOₓN_{y}, MWₓO_{y}, MMoₓO_{y}, MTaₓO_{y}, MTiₓO_{y}, MNbₓO_{y}, MSnO₄.

35. The method of claim 34 wherein the metal oxide layer has a thickness of about 5 nm or less.

36. The method of claim 29 further comprising interposing a high resistance barrier (HRT) layer between the window layer and the TCO layer.
